(19) United States
(12) Patent Application Publication
(10) Pub. No.: US 2023/0087433 A1
(43) Pub. Date: Mar. 23, 2023

(54) REDUCING INTERFERENCE FROM MAGNETIC RESONANCE TOMOGRAPHY UNITS

(71) Applicant: Rainer Schneider, Höchstadt (DE)

(72) Inventor: Rainer Schneider, Höchstadt (DE)

(21) Appl. No.: 17/947,519

(22) Filed: Sep. 19, 2022

(30) Foreign Application Priority Data
Sep. 21, 2021 (DE) 102021210497.5

(51) Int. Cl. G01R 33/422; G01R 33/54

(52) U.S. Cl. CPC G01R 33/422; G01R 33/543

(57) ABSTRACT

Systema and methods to improve the suppression of interference fields outside a magnetic resonance tomography unit. A radiofrequency alternating electromagnetic field of the magnetic resonance tomography unit is generated and measured. A step series is repeated multiple times. The step series includes generating an electromagnetic interference-reduction field for reducing the magnetic field strength at at least one defined location on the basis of a product of a weighting factor and a defined interference-reduction field strength; measuring a magnetic field strength of the generated interference-reduction field; determining an adjustment factor for the weighting factor in such a way as to minimize a sum of the measured field strength of the alternating electromagnetic field and the product of the adjustment factor and the measured interference-reduction field strength; and updating the weighting factor by multiplying by the adjustment factor.

### CROSS REFERENCE TO RELATED APPLICATIONS

This application claims the benefit of DE 102021210497.5 filed on Sep. 21, 2021, which is hereby incorporated by reference in its entirety.

### FIELD

Embodiments relate to a method for operating a magnetic resonance tomography unit.

### BACKGROUND

Magnetic resonance tomography units are imaging facilities that, in order to image an object under examination (also abbreviated below to object or patient), align nuclear spins of the object under examination with a strong external magnetic field, and use an alternating electromagnetic field to excite the nuclear spins to precess about this alignment. The precession or return of the spins from this excited state into a lower-energy state in turn produces as a response an alternating electromagnetic field, that is received by antennas.

Gradient magnetic fields are used to apply spatial encoding to the signals, so that the received signal may subsequently be associated with a volume element. The received signal is then analyzed, and a three-dimensional imaging representation of the object under examination is provided. Local receive antennas, known as local coils, that are arranged directly on the object under examination in order to achieve a better signal-to-noise ratio, may be used to receive the signal. The receive antennas may also be arranged in a patient couch.

Installing a magnetic resonance tomography (MRT) unit is fairly expensive and complex. Apart from the power supply, the cooling, and the helium infrastructure, an MRT apparatus must be housed in a radiofrequency-protected room made of costly copper plates and copper grilles. These installation costs and the fixed enclosure of the MRT unit limit the capabilities and flexibility of the MRT unit.

An RF (radiofrequency)-shielded room must fulfill two fundamental functions: first, the MRT unit must be protected from external RF interference that coincides with the Larmor frequency band (e.g., 65 MHZ for 1.5 T), in order to avoid image artifacts and distortions. Second, other electrical apparatuses must be protected from the MRT unit because the body coil (BC) emits a high RF power during excitation of spins at the Larmor frequency. Without an RF cage, the emission from the body coil would breach the electromagnetic compatibility (EMC) standards by orders of magnitude (factor >500).

If the MRT unit is set up in a room that has no RF-shielding, then RF interference resulting from the BC emission from the body coil may be canceled using additional auxiliary antennas (AUX) mounted on the MRT unit. The destructive superposition of the individual AUX fields and BC fields must be achieved with high precision for cancellation to be successful in this dynamic electromagnetic environment (patient, changing setup conditions, and so on). This high precision is difficult to achieve because of different production tolerances for antennas, cables, and components, but also because of tolerances/non-linearities in the transmit signal chain (individual RF amplifiers, signal delays, etc.) and general hardware errors.

The cancellation or suppression of the BC emission is not required in standard MR scanners because an RF cabin shields the MRT unit from the outside world. Moreover, the precision of individual transmission signal chains is usually achieved by calibration/linearization of each individual RF amplifier. This is not sufficient, however, because the calibration is often performed in a controlled and/or static environment (laboratory or initially by what is known as a tune-up), and/or does not include the entire signal chain (individual amplifiers, e.g., excluding antennas). Furthermore, in the context of interference reduction or Tx cancellation, the interaction of all antennas involved must be taken into account at the same time.

Document WO2019/068687 A2 discloses a magnetic resonance tomography unit having active interference suppression, and a corresponding method for interference suppression. The magnetic resonance tomography unit includes a first receive antenna for receiving a magnetic resonance signal from a patient in a patient tunnel, a second receive antenna for receiving a signal at the Larmor frequency of the magnetic resonance signal, and a receiver. The second receive antenna is located outside or near an opening of the patient tunnel. The receiver includes a signal connection to the first receive antenna and the second receive antenna and is configured to suppress an interference signal received by the second receive antenna in a magnetic resonance signal received by the first receive antenna.

### BRIEF SUMMARY AND DESCRIPTION

The scope of the present disclosure is defined solely by the appended claims and is not affected to any degree by the statements within this summary. The present embodiments may obviate one or more of the drawbacks or limitations in the related art.

Embodiments increase the precision of canceling radiofrequency signals from an MRT unit.

Embodiments provide a method for operating a magnetic resonance tomography unit. The operation may be a normal examination operation but may also be commissioning. For example, the method may be performed before an examination sequence independently thereof. Alternatively, or additionally, the method may be part of an examination sequence.

A radiofrequency alternating electromagnetic field is generated. For example, this electromagnetic field is generated by a body coil of the magnetic resonance tomography unit. The radiofrequency alternating electromagnetic field may also be generated by a local coil, if applicable.

A magnetic field strength of the radiofrequency alternating electromagnetic field is measured. This measurement of the magnetic field strength may be performed at the location at which high-level cancellation of the alternating electromagnetic field is desired. Such a location is typically situated outside the body coil, where this radiofrequency alternating electromagnetic field usually constitutes interference. The magnetic field strength may be measured at a multiplicity of locations outside the body coil or the region of interest of the magnetic resonance tomography unit.

The following interference-reduction algorithm is used for the purpose of precise interference reduction. This interference-reduction algorithm contains a step series that is repeated multiple times.

An electromagnetic interference-reduction field for reducing the magnetic field strength of the radiofrequency alternating electromagnetic field at at least one defined location is generated on the basis of a product of a weighting factor and a defined interference-reduction field strength. For example, the electromagnetic interference-reduction field is generated by one or more antennas or coils. The interference-reduction antennas or coils are arranged, for instance, at the outer edge of a patient tunnel containing the body coil. The electromagnetic interference-reduction field reduces and in an ideal case completely cancels the radiofrequency alternating electromagnetic field, for example through destructive interference. The cancellation or reduction takes place at one or more defined locations. For example, one such defined location is that location at which a sensor is situated for measuring the local magnetic field strength. It is also possible, however, for the defined location to be representative of a multiplicity of spatial points, for instance as is wanted when canceling the far field of a body coil. In this case, it is sufficient to cancel or reduce the radiofrequency alternating electromagnetic field at a defined location, and it may be assumed that this cancellation or reduction is also achieved at other locations in the far field.

A magnetic field strength of the generated interference-reduction field is measured. The measurement may be performed by a sensor at a defined location. In this case, if applicable, a plurality of sensors are provided for detecting the interference-reduction field strength. The magnetic field strength of the generated interference-reduction field may be measured by the same sensor or sensors as the magnetic field strength of the radiofrequency alternating electromagnetic field. It is thereby possible to provide that the reduction in the magnetic field strength is performed at the selected locations by the desired degree.

An adjustment factor for the weighting factor is determined in such a way as to minimize a sum of the measured field strength of the radiofrequency alternating electromagnetic field and the product of the adjustment factor and the measured field strength of the electromagnetic interference-reduction field. Ideally, the sum of the measured field strength of the radiofrequency alternating electromagnetic field and the aforementioned product would be equal to zero. The interference-reduction field would thereby precisely cancel the radiofrequency alternating electromagnetic field at the specific location. Real conditions mean, however, that the sum does not equal zero and optimization must be carried out. It is the measured magnetic field strength rather than the quantity relevant to generating the electromagnetic interference-reduction field that is used for the optimization. It is multiplied by an adjustment factor, where the adjustment factor is optimized such that the sum reaches a minimum. This results in improved interference reduction at the defined measurement location.

Finally in the step series, the weighting factor is updated by multiplying by the adjustment factor. The weighting factor is thus given a value that leads to improved interference reduction. This new value of the weighting factor is the basis for the next repetition of the step series.

Thus, in the repetition of the step series, the updated weighting factor is used, and a corresponding updated interference-reduction field is generated. The updated interference-reduction field is once again measured, and based thereon, a new adjustment factor is determined, from which in turn is obtained an updated new weighting factor. This step series may be repeated any number of times. Ultimately this results in improved reduction in interference from the magnetic resonance tomography unit with regard to unwanted components of the radiofrequency alternating electromagnetic field.

In an embodiment of the method, it is provided that the particular field strength is measured by a plurality of sensors, with a measured value acquired from each sensor, and the measured values together yield a measurement vector for the particular field strength, and the measurement vector contains entries that correspond to the measured field strength at the location of the respective sensors. For instance, four sensors are placed outside the magnetic resonance tomography unit. The magnetic field strength of the alternating field is intended to be as low as possible at these locations of the sensors. Thus, four measured values are obtained from these four sensors at each definable time point. The four measured values form the measurement vector. Hence a multidimensional measurement vector is obtained not only for the radiofrequency alternating electromagnetic field but also for the interference-reduction field. The sum to be minimized for determining the adjustment factor consequently also yields a correspondingly multidimensional vector. By this measurement at a plurality of locations, it is possible to optimize the interference reduction at a plurality of locations simultaneously.

According to an embodiment, the interference-reduction field is generated by a plurality of coils or antennas, and the steps of generating the interference-reduction field and measuring the field strength of the interference-reduction field are performed separately for each of the plurality of coils or antennas. Although in principle the electromagnetic field may be measured using a single sensor, in practice this measurement is be performed using a plurality of sensors, as presented above. In this combination, a measurement vector for the alternating electromagnetic field and one for the interference-reduction field is then obtained for each coil or antenna. Thus, a two-dimensional interference-reduction matrix that includes the number of sensors n as the first dimension and the number of coils or antennas m as the second dimension is obtained for the interference-reduction field. For the optimization, this means that optimized interference reduction may be achieved simultaneously at a plurality of locations using a plurality of coils or antennas.

In an embodiment, the aforementioned step series is repeated multiple times until a defined break criterion is fulfilled. The optimization may thereby be automated and leads to sufficiently precise interference reduction. For example, the break criterion may be that a fixed number of repetition steps are performed. The break criterion may also be, however, that the difference between expected and measured interference-reduction field strengths falls below a defined threshold. This means that the minimum that was sought above is less than a defined threshold value.

In an embodiment of the method, it may be provided that the method is not performed until after an object under examination has been brought into the magnetic resonance tomography unit. This has the advantage that the environment present during the examination of the object also actually exists for the interference reduction. For example, a patient who is in the patient tunnel of the magnetic resonance tomography unit, for example, also influences the radiofrequency interference field that appears outside the patient tunnel. It is therefore important to perform the optimized interference reduction only once the object under examination is in the patient tunnel or in the magnetic resonance tomography unit.

The method may be repeated at defined time intervals or according to defined states or sequence steps of the magnetic resonance tomography unit. For example, the optimization of the interference reduction may thus be performed hourly or daily, for instance as long as this does not interfere with an examination run. Alternatively, the optimized interference reduction may also be performed or repeated from one or more defined states of the magnetic resonance tomography unit. For example, the method may be performed when a patient has been introduced into the patient tunnel. Alternatively, or additionally, the optimization may also be performed after a defined sequence step of the magnetic resonance tomography unit. For example, optimized interference reduction makes sense when, for example, the excitation frequency or the excitation spectrum is changed. Thus, for instance, the interference reduction may be changed multiple times within the examination sequence.

A computer program product is provided that may be loaded directly into a processor of a programmable controller and that contains program code to perform all the steps of a method for operating a magnetic resonance tomography unit when the program product is executed on the controller.

Embodiments include a computer-readable storage medium including electronically readable control information stored thereon, which information is configured to perform, when the storage medium is used in a controller of a magnetic resonance tomography unit, the method for operating the magnetic resonance tomography unit.

Embodiments include a magnetic resonance tomography unit having: an excitation device for generating a radiofrequency alternating electromagnetic field; a measuring device for measuring a magnetic field strength of the radiofrequency alternating electromagnetic field; an interference-reduction device for generating an electromagnetic interference-reduction field for reducing the magnetic field strength of the radiofrequency alternating electromagnetic field at at least one defined location on the basis of a product of a weighting factor and a defined interference-reduction field strength; and a control device for repeating multiple times the step series that includes: generating by the interference-reduction device the electromagnetic interference-reduction field; measuring by the measuring device a magnetic field strength of the generated interference-reduction field; determining by a processing unit of the control device an adjustment factor for the weighting factor in such a way as to minimize a sum of the measured field strength of the radiofrequency alternating electromagnetic field and the product of the adjustment factor and the measured field strength of the electromagnetic interference-reduction field; and updating by the processing unit the weighting factor by multiplying by the adjustment factor.

The advantages and developments mentioned in connection with the above-described method apply mutatis mutandis also to the magnetic resonance tomography unit. In order to carry out the respective functions, the magnetic resonance tomography unit includes an excitation device, that includes one or more coils, for instance a body coil. In addition, the magnetic resonance tomography unit includes a measuring device for measuring the magnetic field strength. The measuring device includes one or more magnetic field sensors, for example. In addition, the magnetic resonance tomography unit includes an interference-reduction device for generating an electromagnetic interference-reduction field. For this purpose, the interference-reduction device includes, for instance, one or more suitable antennas or coils. The magnetic resonance tomography unit also includes a control device for controlling the excitation device, the measuring device, and the interference-reduction device in accordance with the method described. For this purpose, the control device includes a processing unit for processing the data.

The magnetic resonance tomography unit may include a computer, a microcontroller, or an integrated circuit. Alternatively, the magnetic resonance tomography unit may include a real or virtual interconnection of computers (a real interconnection is referred to as a “cluster” and a virtual interconnection is referred to as a “Cloud”).

In an embodiment, the magnetic resonance tomography unit includes an interface, a processor, and a memory unit. An interface may be a hardware or software interface (for instance PCI bus, USB, or FireWire). A processing unit may have hardware elements or software elements, for instance a microprocessor or what is known as a field programmable gate array (FPGA). A memory unit may be implemented as a non-permanent main memory (random access memory or RAM for short) or as a permanent mass storage device (hard disk, USB stick, SD card, solid state disk).

### BRIEF DESCRIPTION OF THE FIGURES

The following description of the embodiments will clarify and elucidate the above-described properties, features and advantages, and the manner in which they are achieved, which embodiments are explained in greater detail in conjunction with the drawings, in which:

FIG. 1 depicts a schematic diagram of an embodiment of a magnetic resonance tomography unit.

FIG. 2 depicts a schematic diagram of a magnetic resonance tomography unit having an interference-suppression transmitter according to an embodiment.

FIG. 3 is a schematic flow diagram of an embodiment of a method.

FIG. 4 is a diagram illustrating the principle of iterative weight optimization according to an embodiment.

### DETAILED DESCRIPTION

The embodiments described in greater detail below constitute one or more embodiments among possible embodiments. The same reference numbers denote identical or similar elements in the figures. In addition, the figures are schematic representations of various embodiments. The elements depicted in the figures are not necessarily shown to scale. Instead, these are depicted in a way that makes their function and purpose clear to a person skilled in the art. The connections shown in the figures between functional units or other elements may also be implemented as indirect connections, where a connection may be wireless or wired. Functional units may be implemented as hardware, software or a combination of hardware and software.

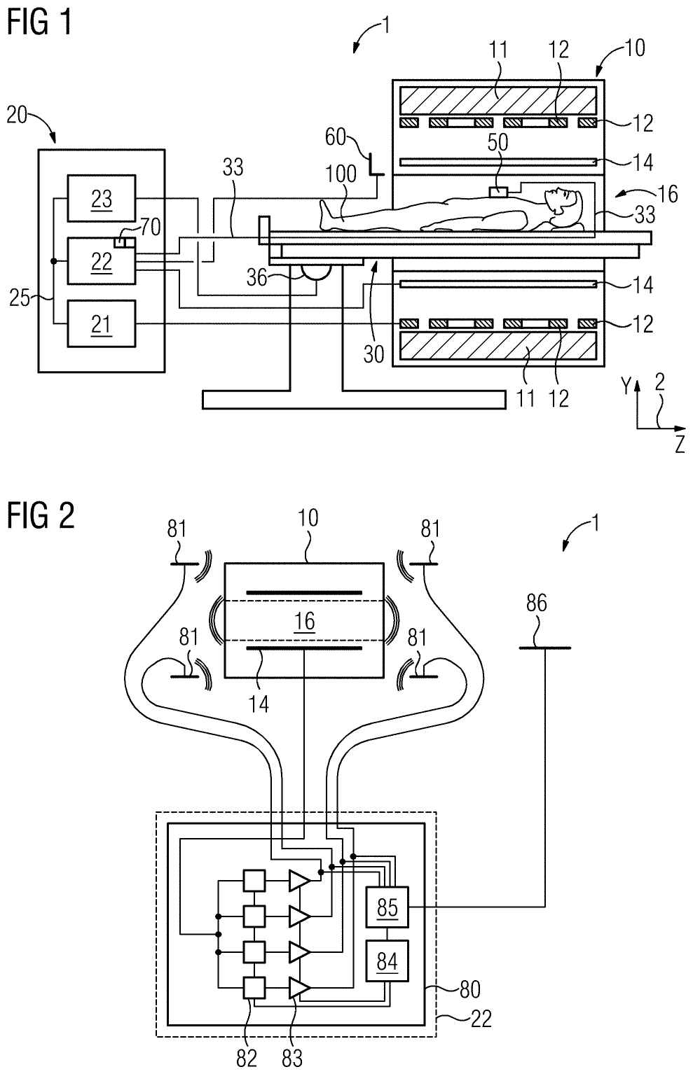

FIG. 1 depicts a schematic diagram of an embodiment of a magnetic resonance tomography unit 1.

A magnet unit 10 of the magnetic resonance tomography unit 1 includes a field magnet 11, that produces a static magnetic field B0 for aligning nuclear spins of samples or of the patient 100 in an acquisition region. The acquisition region is characterized by an extremely homogeneous static magnetic field B0, the homogeneity relating, for example, to the magnetic field strength or magnitude. The acquisition region is approximately spherical and located in a patient tunnel 16, that extends through the magnet unit 10 in a longitudinal direction 2. A patient couch 30 may be moved inside the patient tunnel 16 by the travel unit 36. The field magnet 11 is usually a superconducting magnet, that may provide electromagnetic fields of magnetic flux density of up to 3 T or even higher in the latest equipment. For lower field strengths, however, permanent magnets or electromagnets having normal-conducting coils may also be used.

The magnet unit 10 also includes gradient coils 12, that are configured to superimpose variable magnetic fields in three spatial dimensions on the magnetic field B0 for the purpose of spatial discrimination of the acquired imaging regions in the volume of interest. The gradient coils 12 are usually coils made of normal-conducting wires, that may generate mutually orthogonal fields in the volume of interest.

The magnet unit 10 also includes a body coil 14, that is configured to radiate into the volume of interest a radiofrequency signal supplied via a signal line, and to receive resonance signals emitted by the patient 100 and to output the resonance signals via a signal line.

A control device 20 supplies the magnet unit 10 with the various signals for the gradient coils 12 and the body coil 14 and analyzes the received signals.

Thus, the control device 20 includes a gradient controller 21, that is configured to supply the gradient coils 12 via supply lines with variable currents that provide, coordinated in time, the desired gradient fields in the volume of interest.

In addition, the control device 20 includes a radiofrequency unit 22, that is configured to produce a radiofrequency pulse having a defined variation over time, amplitude, and spectral power distribution for the purpose of exciting magnetic resonance of the nuclear spins in the patient 100. Pulse powers may reach in the region of kilowatts here. The excitation pulses may be emitted via the body coil 14 or via a local transmit antenna into the patient 100.

A controller 23 communicates, for instance via a signal bus 25, with the gradient controller 21 and the radiofrequency unit 22.

Arranged on the patient 100 is a local coil 50 as a first receive coil, that is connected via a connecting line 33 to the radiofrequency unit 22 and its receiver. The body coil 14 may also be implemented as a first receive antenna.

At an edge of the opening of the patient tunnel 16 may be arranged, for instance, four second receive antennas 60, that may be arranged at the corners of a square circumscribed by the circular opening, with the result that the corners lie on the edge of the opening. The four second receive antennas 60 have a signal connection to a receiver 70 of the radiofrequency unit 22. It is conceivable, because there are a plurality of second receive antennas 60, that these do not all have an omnidirectional receive characteristic but, for example, are dipoles, and complement each other by the different orientation to form an omnidirectional characteristic. It would also be conceivable, however, to provide a crossed dipole, for example, as a single second antenna having an omnidirectional characteristic.

It is also possible that alternatively or additionally a second receive antenna 60 is arranged in the patient couch 30.

FIG. 2 depicts a schematic diagram of an embodiment of a magnetic resonance tomography unit 1 including an interference-suppression transmitter 80. Electric waves or alternating fields may also be suppressed by electric fields having the same frequency and amplitude level but opposite polarity or a 180-degree phase-shift. If amplitude levels and/or phases do not match precisely, then the destructive interference at least achieves a reduction. For the purpose of generating these alternating fields for interference suppression or interference reduction (both terms are used here synonymously), a magnetic resonance tomography unit 1 includes an interference-reduction device including one or more interference-suppression antennas 81 arranged around the source of the fields, in this case the patient tunnel 16. The interference-suppression antennas 81 may cover all spatial directions around the opening, and symmetry is employed, for instance equal distances from the opening of the patient tunnel 16 and/or distribution at equal angular spacings with respect to the opening, to simplify controlling the individual interference-suppression antennas 81. Any distribution may be used, however, by an amplitude and phase that may be adjusted individually for each interference-suppression antenna 81. Depending on the type of the alternating field, the antennas may be antennas with electric field, for instance dipoles, or with electromagnetic field, for instance transmit coils. The orientation of the antennas, or the polarization of the generated field, may be aligned with the field directions of the alternating fields to be suppressed.

The signal emitted by the interference-suppression antennas 81 is intended to reduce the emitted radiation of the excitation pulse and hence must have a predefined amplitude and phase relationship to the excitation pulse. Thus, if applicable, for rudimentary interference reduction or interference suppression, the signals are derived in analog form from the excitation pulse or else from the digital pulse generation. Separate units may provide the signals independently of the pulse generation, as long as the necessary amplitude and phase relationship is established.

FIG. 2 indicates symbolically a connecting line between the body coil 14, as the source of the electromagnetic waves, and the interference-suppression transmitter. A direct connection via a power splitter or, for instance, a directional coupler, may be used and also a sensor in the patient tunnel for direct detection of the electromagnetic field would be possible. It would also be possible, however, to extract from a power amplifier or a pulse generator a reference signal for generating the interference-suppression signal.

The reference signal derived from the excitation pulse for the basic interference suppression may then be delayed, or phase-shifted, by adjustable phase shifters 82 for the individual interference-suppression antennas 81, and then amplified in amplitude by adjustable amplifiers 83 before being emitted via the interference-suppression antennas 81.

The adjustment of the phase shifters 82 and the amplifiers 83 is performed by an interference-suppression controller 84 via a signal connection. The interference-suppression controller 84 may adjust phase shifts and amplitudes to predefined values that are determined, for example, during installation of the magnetic resonance tomography unit 1.

The adjustment, or generally the interference reduction, may be performed or initiated by a (calibration) measurement. A calibration receiver 85 may use one or a plurality of spatially distributed sensors or calibration elements 86 of a measuring device to capture the alternating field to be suppressed. Simultaneously, the calibration receiver 85 detects the signals fed to the interference-suppression antennas 81 and transfers the detected values to the interference-suppression controller 84. The interference-suppression controller 84 may then adjust, for instance the interference suppression, the phases, and amplitudes of the individual interference-suppression antennas by a linear optimization method such as LSR in such a way that the field strength becomes zero at the location of the sensors or calibration antenna 86. If the n calibration elements 86 are distributed over the solid angle, then the resultant alternating field from body coil 14 and interference-suppression antennas 81 may be changed into a multipole field having n nulls or lobes, that decrease with distance at a raised power and allow effective suppression.

In principle, the propagation of the fields is reversible. Thus, for the calibration the calibration element(s) 86 emit a signal, and the body coil 14 and the interference-suppression antennas 84 receive the signal, and then the interference-suppression controller 84 determines a suitable phase relationship and amplitudes.

Under ideal conditions, complete Tx cancellation of the BC emission, i.e., the cancellation of the radiofrequency magnetic field penetrating to the outside, is achieved by solving the linear problem of least squares:

Minimize∥\vec{H_{BC}}+H_{TXAux}·\vec{V}∥

where \vec{H_{BC}} is a BC emission vector obtained from N measured values that are measured at N sensor points.

H_{TXAux} is an emission matrix containing N×M field strength values, where N is the number of sensor points and M is the number of AUX antennas that together radiate an interference-reduction field. The vector \vec{V} represents an interference-suppression or interference-reduction weighting vector for the M AUX antennas. A relevant minimum value of the sum shown above may be found my numerical optimization. In the ideal case, \vec{H_{BC}}=−H_{TXAux}·\vec{V}.

The aforementioned real factors mean that the resultant numerically or theoretically optimized AUX interference-reduction vector \vec{H_{TxC Opt}}=H_{TXAux}·\vec{Vₒₚₜ} is very different from the actually measured interference-reduction vector \vec{H_{TxC Meas}}. This leads to insufficient cancellation of the radiofrequency alternating electromagnetic field and the interference-reduction field. In practice, this may be expressed by a varying measured cancellation weighting vector \vec{Vₘₑₐₛ}.

In an embodiment, an iterative calibration and optimization approach is used to overcome quasi-static imperfections in the overall interaction of AUX and BC signal-chain in the real environment. This optimization may be actuated with every patient measurement, for example.

A pseudocode for the optimization is presented below:

| | |
|---|---|
| 1 | Measure the BC emission\vec{H_{BC}} \vec{H_{BC}} |
| 2 | \vec{V}₀ = \vec{V}ᵢₙᵢₜ |
| 3 | While (i=1; i++; i< maximum number of iterations ∥ break criterion reached) |
| 4 | Measure each individual TxAUX signal response with the last optimization |

weight:

| | |
|---|---|
| 5 | For m=1:M |
| 6 | H_{TXAux meas i}(:,m) = measured value from TxAUX channel m with weight · |

\vec{V}ᵢ₋₁(m)

| | |
|---|---|
| 7 | End |
| 8 | Actual measured TxAUX interference-reduction field with the last interference- |

reduction weighting vector (simple sum of all individual TxAUX signal responses)

| | |
|---|---|
| 9 | \vec{H_{TxCMeas i}} = Σₘ₌₁^{M} H_{TXAux meas i}(;,m) |
| 10 | Determine new adjustment vector for the interference reduction |
| - | V_{opt i} argmin_{V}_{_{opt i}}∥\vec{H_{BC}} + H_{TXAux meas i} · \vec{V_{opt ι}}∥ |
| 11 | Theoretical TxAUX interference-reduction field |
| - | \vec{H_{BTxCOpt ι}} = H_{TXAux meas i} · \vec{V_{opt ι}} |
| 12 | Update overall weighting vector \vec{V}_{ι} = \vec{V_{opt ι}} .* \vec{V}ᵢ₋₁ |
| 13 | End |

According to line 1, the radiofrequency alternating electromagnetic field is measured at N sensor sites, yielding the vector \vec{H_{BC}} containing N entries. In line 2, the weighting vector is initialized and is given a defined initialization value for i=0. Lines 3 and 13 describe the start and end of a loop, that is cycled through until a defined maximum number of iterations or a break criterion is reached. In lines 4 to 7, for each individual AUX antenna m individually is measured an associated signal response at the N sensor sites. In order to form the matrix in line 6, these measured values are multiplied by the last optimization weight \vec{V}ᵢ₋₁(m) for the given antenna m. Here the operator “:” means that measured values from all N sensors are determined separately.

Then, according to lines 8 and 9, the actually measured TxAUX interference-reduction field is found as a sum of all the TxAUX signal responses obtained in line 6.

In line 10, a new adjustment vector \vec{V_{opt 1}} is formed, that is obtained from the minimum of the sum of the measured BC emission field and the actually measured interference-reduction matrix multiplied by the corresponding weighting vector. According to line 11, a theoretical, optimum TxAUX interference-reduction field is obtained from each measured interference-reduction field by multiplying by the new adjustment vector \vec{V_{opt 1}}. Finally, according to line 12, the new weighting vector is obtained from the new adjustment vector and the last weighting vector, where the individual entries in the vectors are multiplied by one another, expressed by the operator “.*”.

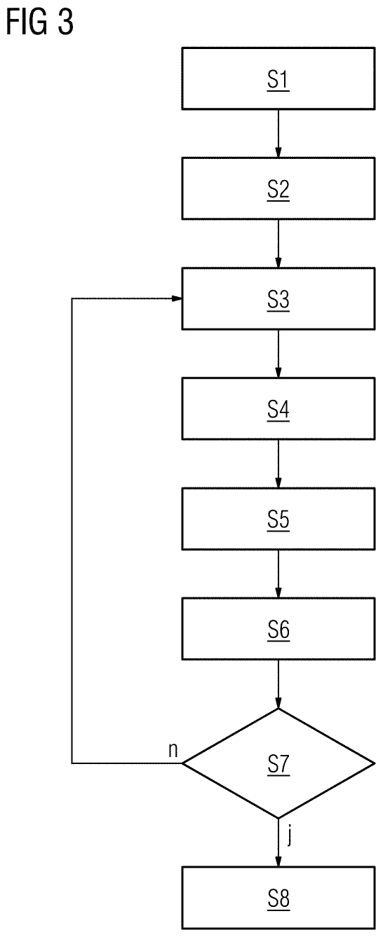

FIG. 3 depicts schematically the method flow of an embodiment. In a first step S1, a radiofrequency alternating electromagnetic field is generated. For example, this alternating field is generated by the body coil 14. In a second step S2, the magnetic field strength of the radiofrequency alternating electromagnetic field is measured. This measurement may be performed by one or more sensors or calibration elements. The measurement locations are usually situated where as large a cancellation as possible of the radiofrequency alternating electromagnetic field is meant to take place. The sensor(s) 86 may be arranged in the environment of the magnet part 10 of the magnetic resonance tomography unit 1.

In a step S3, an electromagnetic interference-reduction field for interference suppression or for reducing the magnetic field strength of the radiofrequency alternating electromagnetic field is generated at at least one defined location on the basis of a product of a weighting factor and a defined interference-reduction field strength. The interference-reduction field may be generated by one or more antennas or coils 81, that are arranged at the exit or entrance of the patient tunnel 16. Step S4 includes measuring a magnetic field strength of the generated interference-reduction field. This measurement of the interference-reduction field may be performed using the same sensors or calibration elements 86 as the measurement of the radiofrequency alternating electromagnetic field to be suppressed.

In a further step S5, an adjustment factor for the weighting factor is determined in such a way as to minimize a sum of the measured field strength of the radiofrequency alternating electromagnetic field and the product of the adjustment factor and the measured field strength of the electromagnetic interference-reduction field. Finally, in a step S6, the weighting factor is updated by multiplying by the adjustment factor.

The steps S3 to S6 constitute a step series that is repeated multiple times: these repetitions always take as a starting point a latest interference-reduction field, that is then optimized by a weighting factor such that the interference field, for example the radiofrequency alternating electromagnetic field, is reduced further.

Therefore, in step S7, a check is performed to ascertain whether a defined number of iteration steps or a break criterion is fulfilled. If the break criterion or the defined iteration count is not yet reached, the method jumps back to step S3, and an improved interference-reduction field is generated. Else, if the break criterion or the required number of iteration steps is reached, the method jumps to step S8, in which the optimized interference-reduction field is used to suppress the radiofrequency alternating electromagnetic field outside the magnetic resonance tomography unit.

Incorrect settings and environmental influences are implicitly captured by the iterative approach, and the interference-reduction or cancellation weights progressively approach the optimum interference-reduction solution. The difference between the numerically optimized and the measured interference-reduction weights decreases with every iteration. The residual precision is then primarily limited by dynamic effects and the stability of the N sensors or antenna measurement points. Therefore, the number of iterations may either be hard-coded or a suitable break criterion may be used, for instance a difference threshold between expected and measured interference-reduction or cancellation vector.

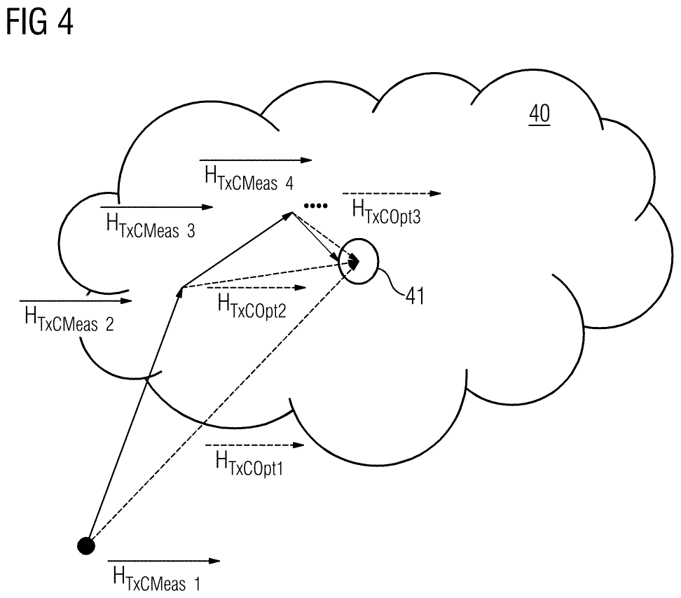

FIG. 4 depicts the optimization in a diagram by way of example. The starting point is an interference-reduction field \vec{H_{TxCMeas 1}} measured in a real situation. In this situation it may be seen that the interference-reduction field does not fully suppress the interference field. The optimum interference-reduction field lies in a solution space 40 at an optimum 41. In this optimum 41, the product \vec{H_{TxAux}}·\vec{V}=−\vec{H_{BC}}. Now an additional theoretical interference-reduction field \vec{H_{TxCOpt 1}} may be determined by the above optimization algorithm. This theoretical interference-reduction field, however, leads in the next iteration step to an actually measured interference-reduction field \vec{H_{TxCMeas 2}}, from which in turn an additional theoretical interference-reduction field \vec{H_{TxCOpt 2}} may be determined. The latter, however, leads in the third iteration step to a measured interference-reduction field \vec{H_{TxCMeas 3}}, from which in turn an additional optimized interference-reduction field \vec{H_{TxCOpt 3}} is determined. In the fourth iteration step, this results in the measured interference-reduction field \vec{H_{TxCMeas 4}} and so on. It may be seen that the interference-reduction field measured in reality gets ever closer to the optimum 41 with each iteration step.

By selecting a suitable calibration RF pulse in line 6 of the above pseudocode for the iterative approach, the iterative interference-reduction weighting vector may be extended in multiple dimensions. For example, the RF pulse may cover a plurality of frequencies and amplitude levels, and an individual calibration weight may be determined accordingly iteratively. It is hence advantageously possible to provide a short and efficient approach to overcoming/correcting hardware imperfections and environmental factors that impair the interference-reduction performance. In addition, a method may thereby be provided for instantaneously determining optimized interference-reduction weights for various amplitude and frequency levels of the Cx chain.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that the dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method for operating a magnetic resonance tomography unit, the method comprising:
generating a radiofrequency alternating electromagnetic field;
measuring a magnetic field strength of the radiofrequency alternating electromagnetic field; and
repeating a step series multiple times, the step series comprising:
generating an electromagnetic interference-reduction field for reducing the magnetic field strength of the radiofrequency alternating electromagnetic field at at least one defined location on the basis of a product of a weighting factor and a defined interference-reduction field strength;
measuring a magnetic field strength of the generated interference-reduction field;
determining an adjustment factor for the weighting factor in such a way as to minimize a sum of the measured field strength of the radiofrequency alternating electromagnetic field and the product of the adjustment factor and the measured field strength of the magnetic interference-reduction field; and
updating the weighting factor by multiplying by the adjustment factor.

2. The method of claim 1, wherein the particular field strength is measured by a plurality of sensors, with a measured value acquired from each sensor, and the measured values together yield a measurement vector for the particular field strength, and the measurement vector corresponds to the measured field strength at the location of the respective sensor.

3. The method of claim 1, wherein the interference-reduction field is generated by a plurality of coils or antennas and generating the interference-reduction field and measuring the field strength of the interference-reduction field are performed separately for each of the plurality of coils or antennas.

4. The method of claim 1, wherein the step series is repeated until a defined break criterion is fulfilled.

5. The method of claim 1, wherein the method is not performed until after an object under examination has been brought into the magnetic resonance tomography unit.

6. The method of claim 1, wherein the method is performed automatically as soon as an object under examination is brought into the magnetic resonance tomography unit.

7. The method of claim 1, wherein the method is repeated at defined time intervals or according to a defined state or sequence step of the magnetic resonance tomography unit.

8. A non-transitory computer implemented storage medium, including machine-readable instructions stored therein, that when executed by at least one processor, cause the processor to:
generate a radiofrequency alternating electromagnetic field;
measure a magnetic field strength of the radiofrequency alternating electromagnetic field; and
repeat a step series multiple times, the step series comprising:
generating an electromagnetic interference-reduction field for reducing the magnetic field strength of the radiofrequency alternating electromagnetic field at at least one defined location on the basis of a product of a weighting factor and a defined interference-reduction field strength;
measuring a magnetic field strength of the generated interference-reduction field;
determining an adjustment factor for the weighting factor in such a way as to minimize a sum of the measured field strength of the radiofrequency alternating electromagnetic field and the product of the adjustment factor and the measured field strength of the magnetic interference-reduction field; and
updating the weighting factor by multiplying by the adjustment factor.

9. The non-transitory computer implemented storage medium of claim 8, wherein the particular field strength is measured by a plurality of sensors, with a measured value acquired from each sensor, and the measured values together yield a measurement vector for the particular field strength, and the measurement vector corresponds to the measured field strength at the location of the respective sensor.

10. The non-transitory computer implemented storage medium of claim 8, wherein the interference-reduction field is generated by a plurality of coils or antennas and generating the interference-reduction field and measuring the field strength of the interference-reduction field are performed separately for each of the plurality of coils or antennas.

11. The non-transitory computer implemented storage medium of claim 8, wherein the step series is repeated until a defined break criterion is fulfilled.

12. The non-transitory computer implemented storage medium of claim 8, wherein the machine-readable instructions are not performed until after an object under examination has been brought into a magnetic resonance tomography unit.

13. The non-transitory computer implemented storage medium of claim 8, wherein the machine-readable instructions are performed automatically as soon as an object under examination is brought into a magnetic resonance tomography unit.

14. The non-transitory computer implemented storage medium of claim 8, wherein the machine-readable instructions are repeated at defined time intervals or according to a defined state or sequence step of a magnetic resonance tomography unit.

15. A magnetic resonance tomography unit comprising:
an excitation device configured for generating a radiofrequency alternating electromagnetic field;
a measuring device configured for measuring a magnetic field strength of the radiofrequency alternating electromagnetic field;
an interference-reduction device configured for generating an electromagnetic interference-reduction field for reducing the magnetic field strength of the radiofrequency alternating electromagnetic field at at least one defined location on the basis of a product of a weighting factor and a defined interference-reduction field strength; and
a control device configured for repeating multiple times a step series comprising:
generating by the interference-reduction device the electromagnetic interference-reduction field;
measuring by the measuring device a magnetic field strength of the generated interference-reduction field;
determining by a processing unit of the control device an adjustment factor for the weighting factor in such a way as to minimize a sum of the measured field strength of the radiofrequency alternating electromagnetic field and the product of the adjustment factor and the measured field strength of the electromagnetic interference-reduction field; and
updating by the processing unit the weighting factor by multiplying by the adjustment factor.

16. The magnetic resonance tomography unit of claim 15, wherein the measuring device comprises a plurality of sensors, wherein a measured value is acquired from each sensor, and the measured values together yield a measurement vector for the particular field strength, and the measurement vector corresponds to the measured field strength at the location of the respective sensor.

17. The magnetic resonance tomography unit of claim 15, wherein the interference-reduction device comprises a plurality of coils or antennas wherein generating the interference-reduction field and measuring the field strength of the interference-reduction field are performed separately for each of the plurality of coils or antennas.

18. The magnetic resonance tomography unit of claim 15, wherein the step series is repeated until a defined break criterion is fulfilled.

19. The magnetic resonance tomography unit of claim 15, wherein the step series is not performed until after an object under examination has been brought into the magnetic resonance tomography unit.

20. The magnetic resonance tomography unit of claim 15, wherein the step series is performed automatically as soon as an object under examination is brought into the magnetic resonance tomography unit.
